(19) United States
(12) Patent Application Publication
(10) Pub. No.: US 2005/0023634 A1
(43) Pub. Date: Feb. 3, 2005

(54) Method of fabricating shallow trench isolation structure and microelectronic device having the structure

(76) Inventors: Byoung-Moon Yoon, Suwon-si (KR); Min-Jin Lee, Seoul (KR); Yong-Sun Ko, Suwon-si (KR); In-Seak Hwang, Suwon-si (KR); Won-Jun Lee, Seoul (KR)

Correspondence Address: HARNESS, DICKEY & PIERCE, P.L.C., P.O. BOX 8910, RESTON, VA, 20195, US

(21) Appl. No.: 10/862,336

(22) Filed: Jun. 8, 2004

(30) Foreign Application Priority Data
Jul. 29, 2003 (KR) 2003-52399

(51) Int. Cl. H01L 21/76; H01L 29/00

(52) U.S. Cl. 257/506; 438/424; 438/435; 257/510

(57) ABSTRACT

Provided is a method of fabricating a shallow trench isolation (STI) structure having a high aspect ratio and improved insulating properties. The exemplary method includes filling a shallow trench isolation region opening with an undoped polysilicon layer, removing an upper portion of the undoped polysilicon layer to form a second opening having a reduced aspect ratio relative to the original opening and filling the second opening with an insulating material to complete the STI structure. Additional protective layers including silicon oxide, silicon nitride and/or a capping layer may be provided on the sidewalls of the opening before depositing the undoped polysilicon.

### CROSS REFERENCE TO RELATED APPLICATIONS

This application claims priority to Korean Patent Application No. 2003-52399, which was filed on Jul. 29, 2003, in the Korean Intellectual Property Office, the disclosure of which is incorporated herein in its entirety by reference.

### BACKGROUND OF THE INVENTION

1. Field of the Invention

The present invention relates to a method of fabricating a shallow trench isolation (STI) structure for a microelectronic device and, more particularly, to a method of fabricating a STI structure having improved gap filling characteristics and a decreased occurrence of voids within the STI structure.

2. Description of the Related Art

The scaling of device patterns must be reduced to produce microelectronic devices offering high performance and high integration. However, as the patterns are scaled down, the aspect ratio of the shallow trench isolation (STI) structure increases. Accordingly, it becomes more difficult to fill the gap within the STI structure without incorporating voids. However, if the depth of the STI structure is decreased in order to reduce the aspect ratio on highly integrated patterns, sufficient element isolation will be compromised; but, if the depth of the STI structure is more suitable for the element isolation, the likelihood of voids generated while filling the gap of the STI structure is increased. The generated voids deteriorate the insulating characteristics of the STI structure and can cause a gate bridge during subsequent patterning processes, leading to a local row failure.

A method of fabricating an STI structure having improved gap filling characteristics is disclosed in U.S. Pat. No. 6,214,698 in which a STI structure is fabricated by filling the STI structure opening with a boron-doped oxide and then performing a reflow process. However, this method does not tend to fill the STI structure without producing any voids if the STI structure has a width of less than 0.2 μm and a high aspect ratio.

### SUMMARY OF THE INVENTION

The present invention provides exemplary methods of fabricating a shallow trench isolation (STI) structure having a high aspect ratio while reducing the likelihood of voids. The present invention further provides an exemplary microelectronic device incorporating a STI structure having a high aspect ratio.

Exemplary embodiments of the present invention provide a method of fabricating a STI structure including etching a predetermined area of a substrate to form a shallow trench isolation opening having a first aspect ratio; filling the shallow trench isolation opening with an undoped polysilicon layer; selectively removing the polysilicon layer through a wet etch-back process with a dilute aqueous ammonia solution to form a first filler that fills a portion of the shallow trench isolation opening unfilled by the first filler has a second aspect ratio less than the first aspect ratio; and filling the remaining shallow trench isolation opening with a second filler.

According to another exemplary embodiment of the present invention, there is provided a shallow trench isolation structure comprising: a shallow trench isolation opening formed in a substrate and having a first aspect ratio; a first filler of undoped polysilicon that fills a portion of the shallow trench isolation opening, and a second filler which fills a remaining shallow trench isolation opening unfilled by the first filler, the remaining shallow trench isolation opening having a second aspect ratio less than the first aspect ratio.

### BRIEF DESCRIPTION OF THE DRAWINGS

The features and advantages of the present invention will become more apparent through the detailed description of exemplary embodiments thereof with reference to the attached drawings in which:

FIGS. 1 through 8 are cross-sectional views illustrating certain steps in a method of fabricating a shallow trench isolation structure according to a first exemplary embodiment of the present invention; and

FIGS. 9 and 10 are cross-sectional views used for illustrating a method of fabricating a shallow trench isolation structure according to a second exemplary embodiment of the present invention.

These drawings are provided for illustrative purposes only and are not drawn to scale. The spatial relationships and relative sizing of the elements illustrated in the various embodiments may have been reduced, expanded or rearranged to improve the clarity of the figure with respect to the corresponding description. The figures, therefore, should not be interpreted as accurately reflecting the relative sizing or positioning of the corresponding structural elements that could be encompassed by an actual device manufactured according to the exemplary embodiments of the invention.

### DETAILED DESCRIPTION OF THE EXEMPLARY EMBODIMENTS

The present invention will now be described more fully with reference to the accompanying drawings, in which exemplary embodiments of the invention are shown. The same reference numerals designate the same or corresponding elements throughout the appended drawings.

According to the exemplary embodiments of the present invention, an opening in a shallow trench isolation (STI) region is filled with an undoped polysilicon layer having good step coverage properties to prevent voids from being generated. Further, because only the undoped polysilicon layer is selectively removed through a high temperature wet etch-back process using a diluted aqueous ammonia solution, the aspect ratio of the STI region may be reduced. Because a pad oxide layer or an oxide layer exposed during the wet etch-back process is etched, the generation of voids is effectively prevented.

Devices to which the method of fabricating the STI structure according to the present invention can be applied are microelectronic devices, such as highly integrated semiconductor devices, microprocessors, microelectromechanical devices, optoelectronic devices and display devices.

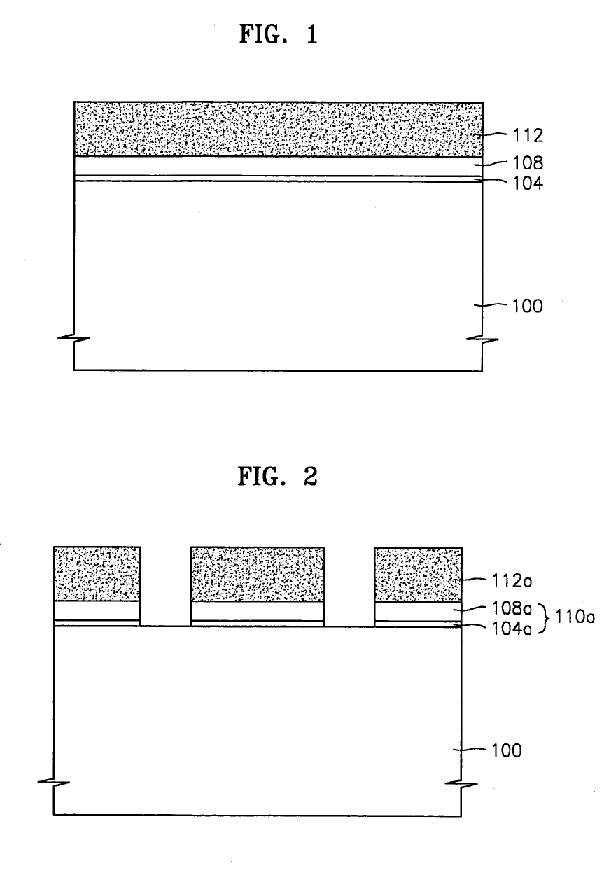

A 256-megabit dynamic random access memory (DRAM) having a STI structure width of 0.2 μm or less, will be used below for describing an exemplary embodiment of the present invention. FIGS. 1 through 8 are cross-sectional views used to illustrate a method of fabricating an STI structure according to a first exemplary embodiment of the present invention.

As illustrated in FIG. 1, a pad oxide layer 104 and a nitride layer 108 are sequentially formed on a substrate 100 comprising, for example, a silicon wafer. Subsequently, an organic antireflection coating (ARC) layer (not shown) and a photoresist 112 are layer formed on the nitride layer 108. The pad oxide layer 104 is used to reduce the stress applied between the substrate 100 and the nitride layer 108. The pad oxide layer 104 typically has a thickness ranging from about 20 to 200 Å, preferably about 100 Å.

The nitride layer 108 is used as a hard mask during an etching process for forming an STI region. The nitride layer 108 is formed by depositing a silicon nitride layer in thickness ranging from about 500 to 2000 Å, preferably about 800 to 850 Å. The deposition process is generally performed using chemical vapor deposition (CVD), sub-atmospheric chemical vapor deposition (SACVD), low pressure chemical vapor deposition (LPCVD) or plasma enhanced chemical vapor deposition (PECVD).

As illustrated in FIG. 2, a photoresist pattern 112a is then formed to define active and isolation regions on the substrate. Next, the nitride layer 108 and the pad oxide layer 104 are etched using a dry etching method using the photoresist pattern 112a as a mask to form a pad mask 110a consisting of a nitride layer pattern 108a and a pad oxide layer pattern 104a. The nitride layer 108 may be etched using a fluorocarbon gas, i.e., a CₓF_{y} or CₐH_{b}F_{c} gas, such as CF₄, CHF₃, C₂F₆, C₄F₈, CH₂F₂, CH₃F, CH₄, C₂H₂ and C₄F₆, or a mixture of such gases. An inert gas, such as Ar gas, can also be used as an atmospheric, carrier, diluting and/or purge gas.

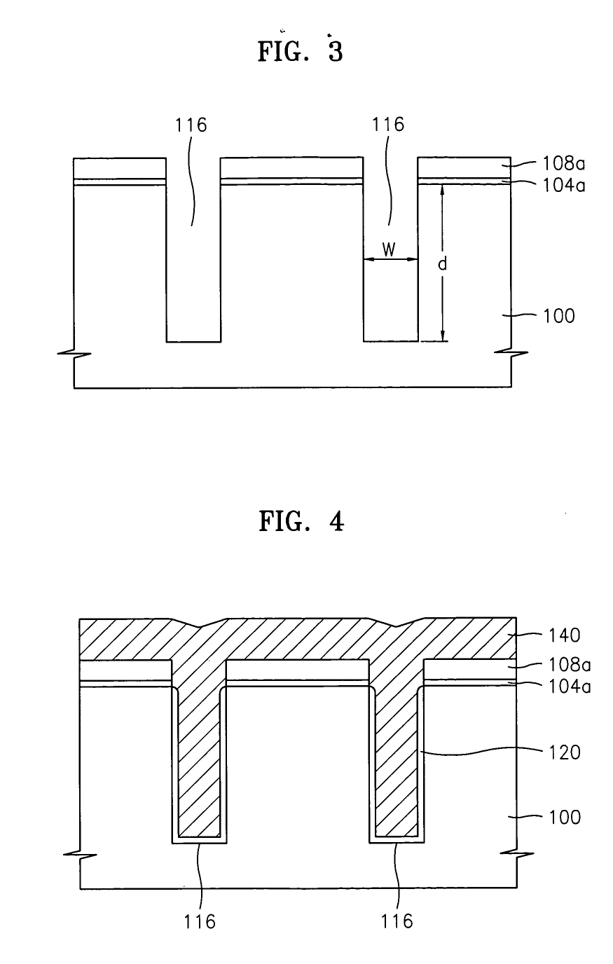

As illustrated in FIG. 3, the photoresist pattern 112a is then removed. Exposed portions of the substrate 100 are then subjected to an anisotropic dry etch using the pad mask 110a as an etching mask to form an opening in STI region 116 which defines and separates adjacent active regions. The photoresist pattern 112a may be removed using any conventional method, for example, oxygen plasma ashing and/or organic stripping. In highly integrated designs, the STI region 116 will have a width w less than 0.2 μm and a depth d sufficient for element isolation, resulting in an aspect ratio R of d/w.

As illustrated in FIG. 4, a silicon oxide layer 120 is formed on the exposed silicon surfaces of the STI region 116. In particular, the silicon oxide layer 120 is formed on the inner sidewalls and bottom of the STI region 116 to correct damage generated during the etching process used to form the opening in the STI region 116. The silicon oxide layer 120 may be a thermal oxide layer or a CVD oxide layer and will typically have a thickness ranging from about 20 to 200 Å.

Next, the opening in the STI region 116 over which the silicon oxide layer 120 is formed is filled with a first filling layer 140. It is preferred that an undoped polysilicon layer having excellent gap filling characteristics be used as the first filling layer 140 to reduce or prevent the generation of voids. The undoped polysilicon layer is preferably formed using an LPCVD method in which the process pressure is reduced to no more than several Torr using a pump to produce an environment in which a reactive gas may be rapidly diffused.

Accordingly, under such conditions, the reactive gas will diffuse rapidly to the surfaces of the substrate 100. If the surface reaction rate consumes the reactive gas(es) more slowly than the rate at which the reactive gas diffuses to the substrate surfaces, the deposition of the filling layer 140 is determined by the reaction rate. Accordingly, a layer having good step coverage and good gap filling characteristics can be formed. For example, silane (SiH₄) gas may be thermally decomposed at a temperature of 600 to 700° C., preferably 600 to 650° C. and at a pressure of 0.1 to 1.0 Torr to form a first filling layer 140 of the undoped polysilicon.

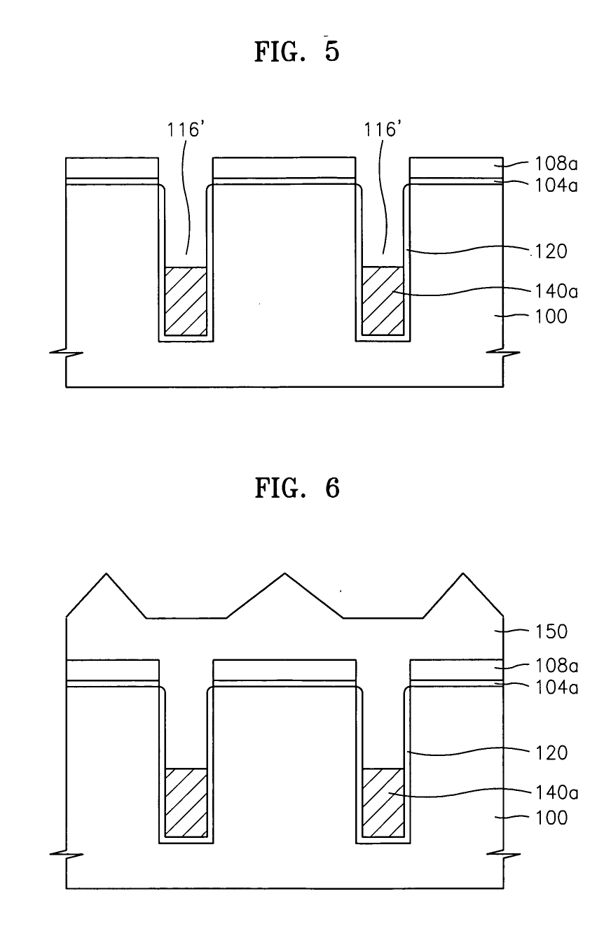

As illustrated in FIG. 5, an upper portion of the first filling layer 140 is then selectively removed to form a first filler 140a that fills a portion of the opening in the SYI region 116. An aspect ratio of a remaining STI region 116′ which is not filled by the first filler 140a is less than the aspect ratio of the STI region 116. The undoped polysilicon layer used as the first filling layer 140 is selectively removed so that a second filler may be used to fully fill the remaining STI region 116′ while reducing the risk of generating voids. When a high density plasma (HDP) oxide. layer is uHDP) oxide layer is used as the second filler, the aspect ratio of the remaining STI region 116′ is preferably less than 3.

The first filling layer 140 is preferably removed using a wet etch-back process in which an etchant having a high etching selectivity with respect to other circumferential layers that may be exposed during the wet etch-back process, e.g., the pad oxide pattern 104a, the oxide layer 120 and the nitride layer pattern 108a, so as not to alter the profiles of the circumferential layers. In particular, it is important that the pad oxide layer pattern 104a and/or the silicon oxide layer 120 must not be etched to any significant degree to reduce the likelihood that voids will be generated at side surfaces during the etching process. Accordingly, an etchant that will remove substantially only the first filling layer 140 should be used.

A diluted aqueous solution of ammonia having a deionized water to ammonia ratio of 5:1 to 100:1, preferably about 10:1, is suitable for the etchant. The wet etch-back process may be performed at a temperature of 60 to 90° C., preferably at about 80° C. The wet etch-back process is performed in a such a manner that an etching ratio of the pad oxide layer pattern 104a or the silicon oxide layer 120 to the undoped polysilicon layer is less than about 1:50. When a dilute ammonia solution at a ratio of 10:1 is used at a temperature of 80° C., etching ratios of the oxide layer: the nitride layer: the undoped polysilicon layer of about 1:1:200 have been observed.

As illustrated in FIG. 6, the remaining STI region 116′ is filled with the second filling layer 150. The second filling layer 150 may be an insulating material selected from a group consisting of undoped silicate glass (USG), HDP oxide tetraethylortholsilicate (TEOS) formed using PECVD, an oxide formed using PECVD, and combinations thereof. Of the insulating materials, HDP oxides, which typically exhibit a fine grain and good density, are preferred for filling the remaining STI region 116′.

A HDP CVD process is a technology combining an etching method using CVD and sputtering. During the HDP CVD process, a deposition gas for forming a material layer is supplied into a chamber and a sputtering gas for etching the deposited material layer through sputtering is also supplied into the chamber. Accordingly, SiH₄ and O₂ are supplied into the chamber as the deposition gas, and an inactive gas, e.g., Ar gas, is supplied into the chamber as the sputtering gas. A portion of the supplied deposition and sputtering gases is ionized within the chamber due to a high frequency power to form a plasma. Further, because a biased high frequency power is applied to a wafer chuck, e.g., an electrostatic chuck, within the chamber on which a substrate is loaded, the ionized deposition gas and sputtering gas diffused more rapidly toward the surface of the substrate. The deposition gas ions form a silicon oxide layer, while the sputtering gas ions sputter the deposited silicon oxide layer. When the HDP oxide layer is formed as the second filling layer 150 through this manner, the second filling layer 150 has a fine grain and a dense quality, good gap filling characteristics, and a top surface profile as illustrated in FIG. 6.

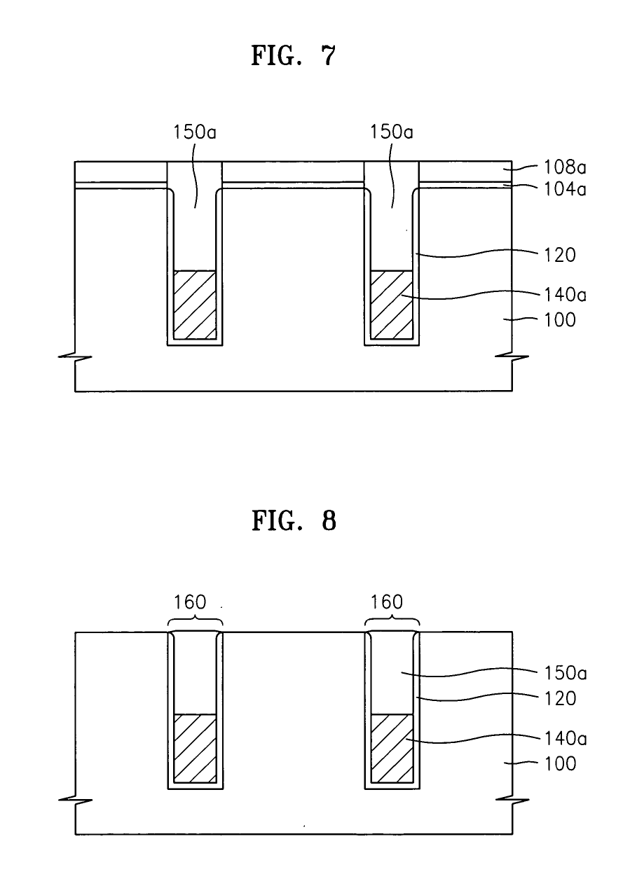

As illustrated in FIG. 7, an upper portion of the second filling layer 150 is planarized to expose the surface of the pad mask 110a. The planarization process may be performed using chemical mechanical polishing (CMP) or etch-back With the nitride layer pattern 108a being used as a planarization stopper or stopping layer. For example, when a HDP oxide is used as the second filling layer 150 and planarized using CMP, the nitride layer pattern 108a functions as a CMP stopper. It is preferable to select a CMP slurry composition that will remove the HDP oxide 150 more rapidly than the nitride layer pattern 108a such as a slurry incorporating a ceria abrasive.

As illustrated in FIG. 8, the pad mask 110a is removed to complete an STI structure 160 filled with the first filler 140a and a second filler 150a. The nitride layer pattern 108a of the pad mask 110a may be removed using phosphoric acid, and the pad oxide layer pattern 104a may be removed using diluted HF or a buffered oxide etchant (BOE) which is a mixture of NH₄F, HF and deionized water.

Active elements such as transistors and passive elements such as capacitors may then be formed on the active region of the substrate 100 defined by the completed STI structure 160 using any conventional process for fabricating semiconductor devices.

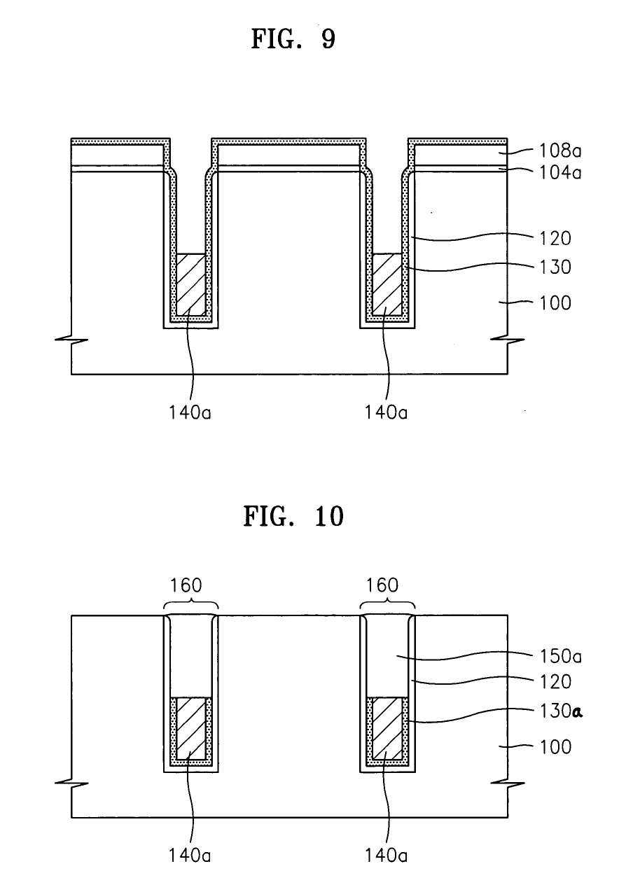

FIGS. 9 and 10 are cross-sectional views that illustrate a method of fabricating an STI structure according to a second exemplary embodiment of the present invention. Elements having the same functions as those described in the first exemplary embodiment are given the same reference numerals and a detailed explanation thereof will be omitted.

As illustrated in FIG. 9, the silicon oxide layer 120 is formed on inner sidewalls of the STI region 116 in the same manner as described with reference to FIGS. 1 through 4. A nitride layer 130 is then formed over the resultant structure after formation of the silicon oxide layer 120. It is preferred that the nitride layer 130 be conformal to form a liner of generally uniform thickness along the sidewalls of the STI region 116. The nitride layer 130 protects the oxide layer 120 from further oxidation during subsequent processes and improves the insulating characteristics of the final STI structure 160 shown in FIG. 10. The nitride layer 130 will typically have a thickness of about 50 to 300 Å.

A capping layer (not shown) may also be selectively formed on the nitride layer 130 to protect the nitride layer 130 from damage during subsequent processes. If present, the capping layer may be formed from a middle temperature oxide (MTO).

The STI region 116 on which the nitride layer 130 is formed is then filled with a first filling layer 140, and then, the upper portion of the first filling layer 140 is selectively removed to form the first filler 140a in a similar manner to that described above with reference to FIGS. 4 and 5. When removing the upper portion of the first filling layer 140, only the first filling layer 140 should be removed to limit damage to the profiles of the pad oxide layer pattern 104a, the nitride layer pattern 108a, and the liner nitride layer 130.

As illustrated in FIG. 10, the portion of the nitride layer 130 exposed when the first filler 140a is formed may then be removed using phosphoric acid, so that the remaining portion of the nitride layer 130a and the first filler 140a have substantially the same height. Next, the remaining portion of the STI region 116′ is filled with the second filling layer 150. The exposed upper portion of nitride layer 130 is preferably removed before the second filling layer 150 is formed so that when the nitride layer pattern 108a is removed using phosphoric acid in the following process after the planarization process, no portion of the nitride layer 130a will be removed between the filler and substrate resulting in element defects. The second filling layer 150 may then be planarized and the pad mask 110a removed in the same manner as described above with reference to FIGS. 6-8 to complete the STI structure 160.

The exemplary methods of fabricating the STI structure according to the present invention can form STI structures having a depth suitable for element isolation while reducing the risk of voids even for narrow, high aspect ratio STI structures. Accordingly, the exemplary methods can provide STI structures having improved isolation characteristics.

While the present invention has been particularly shown and described with reference to exemplary embodiments thereof, it will be understood by those of ordinary skill in the art that various changes in form and details may be made therein without departing from the spirit and scope of the present invention as defined by the following claims.

1. A method of forming an isolation structure in a substrate comprising:
forming an opening in the substrate having an aspect ratio R₁;
filling the opening with a non-conductive material;
removing an upper portion of the non-conductive material to form a second opening having an aspect ratio R₂;
filling the second opening with an insulating material.

2. A method of forming an isolation structure in a substrate according to claim 1, wherein forming the opening in the substrate includes:
forming a pad layer on a substrate surface;
forming a second layer on the pad layer;
forming an isolation pattern on the second layer to expose portions of the second layer;
removing the portion of the second layer and the pad layer below the exposed portions of the second layer to expose portions of the substrate; and
removing a portion of the substrate below the exposed portions of the substrate to create a first opening into the substrate.

3. A method of forming an isolation structure in a substrate according to claim 2, wherein filling the opening with a non-conductive material includes:
depositing a layer of a non-conductive material on the substrate to fill the opening;
removing a first upper portion of the non-conductive material to expose a surface of the second layer and form a planarized structure;
removing a second upper portion of the non-conductive material to form the second opening into the substrate.

4. A method of forming an isolation structure in a substrate according to claim 3, wherein filling the opening with a non-conductive material includes:
forming a first protective layer on surfaces of the substrate exposed within the opening before depositing a layer of a non-conductive material on the substrate to fill the opening.

5. A method of forming an isolation structure in a substrate according to claim 5, wherein:
the first protective layer is a silicon oxide.

6. A method of forming an isolation structure in a substrate according to claim 5, wherein forming the first protective layer includes:
oxidizing the surfaces of the substrate exposed within the opening.

7. A method of forming an isolation structure in a substrate according to claim 5, wherein first protective layer has a thickness of between about 20 and about 200 Å.

8. A method of forming an isolation structure in a substrate according to claim 4, wherein filling the opening with a non-conductive material includes:
forming a second protective layer on the first protective layer before depositing a layer of a non-conductive material on the substrate to fill the opening.

9. A method of forming an isolation structure in a substrate according to claim 8, wherein:
the second protective layer is silicon nitride.

10. A method of forming an isolation structure in a substrate according to claim 1, wherein:
the substrate is silicon;
the non-conductive material is undoped polysilicon;
the insulating material includes a material selected from a group consisting of undoped silicate glass (USG), silicon oxide and tetraethylortholsilicate (TEOS).

11. A method of forming an isolation structure in a substrate according to claim 10, wherein:
filling the opening with undoped polysilicon includes low pressure chemical vapor deposition (LPCVD); and
filling the second opening with the insulating material includes a process selected from a group consisting of high density plasma chemical vapor deposition (HDPCVD), chemical vapor deposition (CVD), plasma enhanced chemical vapor deposition (PECVD), sub-atmospheric chemical vapor deposition (SACVD) and LPCVD.

12. A method of forming an isolation structure in a substrate according to claim 10, wherein removing the upper portion of the non-conductive material to form the second opening includes:
etching the non-conductive material with an aqueous ammonia solution, the ammonia solution having a water: ammonia ratio of between about 5:1 and 100:1 by weight percent.

13. A method of forming an isolation structure in a substrate according to claim 12, wherein:
the aqueous ammonia solution is maintained at an etch temperature of between about 60 to about 90° C. while etching the non-conductive material; and wherein
the aqueous ammonia solution preferentially removes the non-conductive material at an etch rate that is at least 50 times greater than a rate at which silicon oxide or silicon nitride are removed while etching the non-conductive material.

14. A method of forming an isolation structure in a substrate according to claim 1, wherein:
the first aspect ratio, R₁, is at least 5; and
the second aspect ratio, R₂, is no greater than 3.

15. A method of forming an isolation structure in a substrate according to claim 13, wherein:
the opening has a width w that is no greater than about 0.2 μm.

16. A semiconductor device having a substrate that includes active areas separated by shallow trench isolation (STI) regions formed in the substrate, wherein the STI regions comprise:
a first filler material in a lower portion of the STI region; and
a second filler material formed above the first filler material in an upper portion of the STI region;
wherein the first and second filler materials cooperate to form the STI region and separate adjacent active areas.

17. A semiconductor device according to claim 16, wherein:
side surfaces of the first and second filler materials are surrounded by an oxide layer.

18. A semiconductor device according to claim 17, wherein:
a nitride layer is arranged between the side surfaces of the first filler material and the surrounding oxide layer.

19. A semiconductor device according to claim 16, wherein:
the second filler material has a width w, a height h, and an aspect ratio R₂ equal to h/w, the aspect ratio being less than 3.

20. A semiconductor device according to claim 19, wherein:
the first filler material is undoped polysilicon; and
the second filler material is an oxide and has an upper surface that is substantially coplanar with an upper surface of the substrate.
